(19) United States
(12) Patent Application Publication
(10) Pub. No.: US 2019/0003075 A1
(43) Pub. Date: Jan. 3, 2019

(54) SINGLE CRYSTAL INGOT GROWING APPARATUS

(71) Applicant: SK SILTRON CO., LTD., Gumi-si, Gyeongsangbuk-do (KR)

(72) Inventors: In Gu KANG, Gumi-si (KR); Do Won SONG, Gumi-si (KR); Sung Chan LEE, Gumi-si (KR); Ho Sub JUNG, Gumi-si (KR)

(21) Appl. No.: 16/063,855

(22) PCT Filed: Feb. 20, 2017
(86) PCT No.: PCT/KR2017/001864

§ 371 Date: Jun. 19, 2018

(30) Foreign Application Priority Data
Nov. 17, 2016 (KR) 10-2016-0153162

(51) Int. Cl. C30B 15/10; C30B 15/14; C30B 15/00; C30B 15/20; C30B 15/30; C30B 29/06; C30B 35/00

(52) U.S. Cl. CPC C30B 15/10; C30B 15/14; C30B 15/007; C30B 35/002; C30B 15/30; C30B 29/06; C30B 15/20

(57) ABSTRACT

The present invention relates to a single crystal ingot growing apparatus capable of precisely controlling an Ox volatilization on a silicon melt solution surface by uniformly forming a flow velocity of an inert gas flowing along the silicon melt solution surface. The present invention provides a single crystal ingot growing apparatus, including: a crucible containing a silicon melt solution; a heat shielding member mounted to hang above the crucible and cooling a single crystal ingot grown from the silicon melt solution of the crucible; a first flow path formed between an outer circumferential surface of the single crystal ingot and an inner circumferential surface of the heat shielding member, in which an inert gas is vertically moved downward; and a second flow path formed between a lower end of the heat shielding member and an upper surface of the silicon melt solution, in which the inert gas is horizontally moved outward, wherein an oxygen concentration in the single crystal is controlled depending on a volume ratio of the second flow path to the first flow path.

### TECHNICAL FIELD

The present invention relates to a single crystal ingot growing apparatus capable of precisely controlling an Ox volatilization on a silicon melt solution surface by uniformly forming a flow velocity of an inert gas flowing along a silicon melt solution surface.

### BACKGROUND ART

Generally, a single crystal growing apparatus supplies polycrystalline silicon in a solid state to inside of a crucible, then, the crucible is heated to form a liquid silicon melt solution, and a seed for agglomerating seed crystals is added in a silicon melt solution to rotate and pull up simultaneously, and thus a single crystal ingot having a desired diameter is grown.

Generally, when manufacturing a single crystal ingot using the Czochralski method, a quartz crucible is essentially used to contain a silicon melt solution melted by a heater.

However, the quartz crucible is transferred in a form of SiOx from being dissolved in a melt solution reflecting a high temperature silicon melt solution and finally is mixed into a single crystal via a solid-liquid interface.

At this point, the SiOx mixed into the single crystal promotes a strength of a wafer and forms a bulk micro defect (BMD), which acts as a gettering site for metal impurities during a semiconductor process, or causes various crystal defects and segregation therein, which are factors adversely affecting a yield of a semiconductor device.

Therefore, when growing a silicon single crystal using the Czochralski method, it is necessary to appropriately control an oxygen concentration, flowing into the crystal via the solid-liquid interface.

According to the related art, the oxygen concentration in an axial direction of the single crystal ingot is controlled via a dissolution rate of the quartz crucible, a flow pattern of the silicon melt solution, and an Ox volatilization control from a silicon melt solution surface.

Japanese Patent Publication No. 2015-089854 discloses a manufacturing method of a silicon single crystal in which an oxygen concentration of a crystal is controlled by controlling Ox volatilization from a silicon melt solution surface, by controlling a flow velocity of an inert gas depending on a porosity obtained, by which a distance between a single crystal ingot and a heat shield is divided by a cross-sectional area of the single crystal ingot.

FIG. 1 is a graph illustrating a flow velocity of an inert gas depending on a porosity change against a crystal diameter in a conventional single crystal ingot growing apparatus.

According to the related art, a distance between the single crystal ingot and the heat shield is converted into the porosity. As shown in FIG. 1, when the porosity is small, the larger a flow velocity of argon (Ar) which is the inert gas, the greater an oxygen concentration deviation in the crystal. On the other hand, when the porosity is large, the larger the flow velocity of argon (Ar), the less the oxygen concentration deviation in the crystal, but it can be confirmed that the oxygen concentration deviation in the crystal is generated relatively large depending on the porosity.

However, according to the related art, since a flow velocity of the inert gas is controlled in consideration of only a distance between the single crystal ingot and the heat shield, there is a limit in controlling Ox volatilization from a silicon melt solution surface. As a result, there is a problem that the oxygen concentration deviation in the crystal is not solved.

### DETAILED DESCRIPTION OF INVENTION

### Technical Problem

The present invention is directed to solving the above described problems in the related art and providing a single crystal ingot growing apparatus capable of precisely controlling an Ox volatilization on a silicon melt solution surface by uniformly forming a flow velocity of an inert gas flowing along the silicon melt solution surface.

### Technical Solution

The present invention provides a single crystal ingot growing apparatus, including: a crucible containing a silicon melt solution; a heat shielding member mounted to hang above the crucible and cooling a single crystal ingot grown from the silicon melt solution of the crucible; a first flow path formed between an outer circumferential surface of the single crystal ingot and an inner circumferential surface of the heat shielding member, in which an inert gas is vertically moved downward; and a second flow path formed between a lower end of the heat shielding member and an upper surface of the silicon melt solution, in which the inert gas is horizontally moved outward, wherein an oxygen concentration in the single crystal is controlled depending on a volume ratio of the second flow path to the first flow path.

In addition, it is preferable that the volume ratio of the second flow path to the first flow path is limited to 1.4 to 1.6.

Further, it is more preferable that the volumes of the first and second flow paths are set so that a velocity deviation of the inert gas flowing along the first and second flow paths is within 0.5 cm/sec.

Furthermore, it is more preferable that the oxygen concentration in the single crystal is controlled by changing a flow rate of the inert gas when a target oxygen concentration is changed during a growth process of the single crystal ingot.

Meanwhile, the single crystal ingot growing apparatus further includes a tube extending downward at a lower side of the inner circumferential surface of the heat shielding member, wherein the volume ratio of the second flow path to the first flow path may be varied depending on at least one of an inner diameter (d) of the heat shielding member, a length (L) of the tube, and a melt gap (M/G).

In addition, it is preferable that the volume ratio of the second flow path to the first flow path is set so as to control an oxygen concentration deviation (Max-Min) in an axial direction of the single crystal ingot to 1.5 ppma or less.

Further, it is preferable that the volume ratio of the second flow path to the first flow path is set so as to control an oxygen concentration deviation (Max-Min) in a radial direction of the single crystal ingot to 0.65 ppma or less.

### Advantageous Effects

A single crystal ingot growing apparatus according to the present invention may control an oxygen concentration in a single crystal in consideration of a flow path between a heat shielding member and a single crystal ingot, and a flow path between the heat shielding member and an upper surface of a silicon melt solution.

Therefore, a flow velocity of an inert gas flowing along a surface of the silicon melt solution may be controlled to be constant, thereby accurately controlling an Ox volatilization on the silicon melt solution surface. Thus, as a result, the oxygen concentration can be uniformly formed in an axial direction and a radial direction of the single crystal ingot.

### DESCRIPTION OF DRAWINGS

FIG. 1 is a graph illustrating a flow velocity of an inert gas depending on a porosity change against a crystal diameter in a conventional single crystal ingot growing apparatus.

FIG. 2 is a side cross-sectional view illustrating a single crystal ingot growing apparatus according to an embodiment of the present invention.

FIG. 3 is a schematic view schematically illustrating a main part of a flow path through which an inert gas flows according to the present invention.

FIGS. 4 and 5 are graphs illustrating an oxygen concentration in an axial direction and a radial direction of the single crystal ingot according to a volume ratio change of the flow path shown in FIG. 3.

FIG. 6 is a graph illustrating an oxygen concentration and a flow velocity of an inert gas in an axial direction of the single crystal ingot according to a volume ratio change of the flow path shown in FIG. 3.

FIGS. 7 and 8 are graphs illustrating oxygen concentrations in an axial direction and a radial direction of the ingots manufactured by the conventional single crystal ingot growing apparatus and the single crystal ingot growing apparatus of the present invention.

### MODES OF THE INVENTION

Hereinafter, the embodiments will be described in detail with reference to the accompanying drawings. However, the scope of the spirit of the present invention may be determined from the matters disclosed in the embodiments, and the spirit of the present invention of the embodiments include practical modifications such as addition, deletion, modification, and the like of components to the following proposed embodiments.

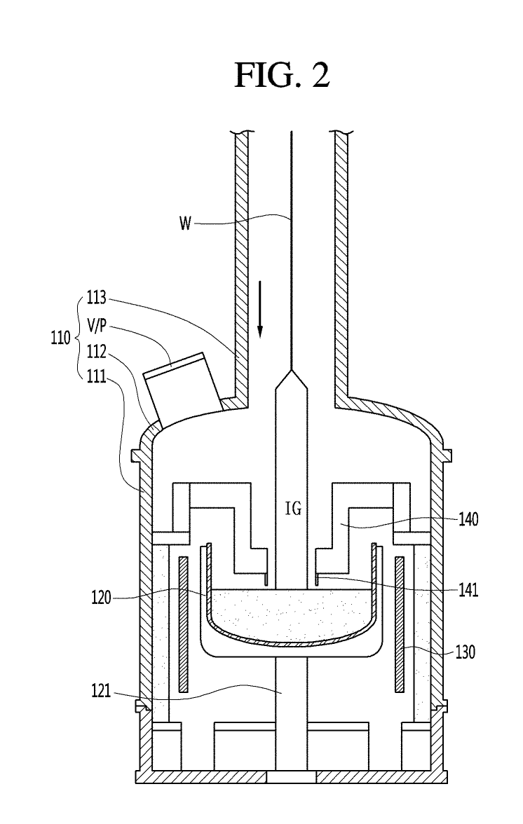

FIG. 2 is a side cross-sectional view illustrating a single crystal ingot growing apparatus according to an embodiment of the present invention.

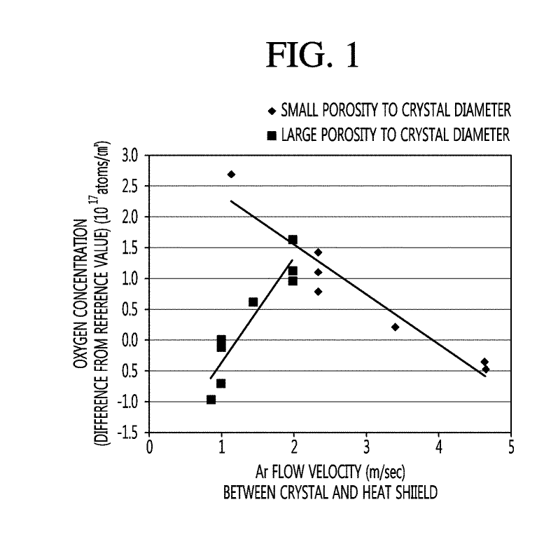

The present invention provides the single crystal ingot growing apparatus including a crucible 120, a heater 130, and a heat shielding member 140 inside a chamber 110 as shown in FIG. 1 to grow a single crystal ingot from a silicon melt solution, and an operation thereof is controlled by a separate control unit (not shown).

The chamber 110 provides a predetermined closed space in which an ingot (IG) is grown, and various components are mounted inside/outside.

In the embodiment, the chamber 110 may include: a cylindrical-shaped body part 111 in which the crucible 120, the heater 130, and the heat shielding member 140 are embedded; a dome-shaped cover part 112 coupled to an upper side of the body part 111 and provided with a view port (V/P) capable of observing an ingot growing process; a cylindrical-shaped pulling part 113 coupled to an upper side of the cover part 112 and providing a space in which the ingot may be pulled up.

At this point, an inert gas such as argon (Ar) flows in a downward direction from an upper side of the chamber 110, and the control unit (not shown) may control a flow rate and a flow velocity of the inert gas.

In addition, a seed cable W hanging a seed crystal, and a drum (not shown) on which the seed cable W is wound, are provided on the chamber 110, and the control unit (not shown) may control a pulling speed by controlling an operation of the drum (not shown).

The crucible 120 is a container containing a solid silicon melt solution and is rotatably mounted inside the chamber 110. Further, the crucible 120 may block an inflow of impurities and also withstand a high temperature. In the embodiment, a quartz crucible and a graphite crucible may be overlapped. An Ox component is included in the silicon melt solution while the quartz crucible is partially melted at a high temperature.

Furthermore, a crucible driving unit 121 for rotating and elevating the crucible 120 is provided at lower side of the crucible 120, and the control unit (not shown) controls an operation of the crucible driving unit 121 and may control a rotational speed and an elevating speed.

The heater 130 is provided on a circumference of the crucible 120 and liquefies a poly-shaped raw material contained in the crucible 120 into the silicon melt solution as the crucible 120 is heated. Similarly, the control unit (not shown) may control an operation of the heater 130 so as to control a temperature inside the chamber 110.

The heat shielding member 140 is provided to directly cool the ingot (IG) to be grown from a high-temperature silicon melt solution. The heat shielding member 140 is made of a graphite material capable of withstanding a high temperature, which is mounted to hang above the crucible 120.

Specifically, a lower part of the heat shielding member 150 is mounted so as to cover up a circumference of the ingot (IG) grown from the silicon melt solution contained in the crucible 120 at a predetermined interval, and so as to maintain a predetermined distance from a silicon melt solution surface.

In addition, a tube 141 protruding downward is provided on a lower side of an inner circumferential surface of the heat shielding member 140, and a gap between a lower end of the tube 141 and the silicon melt solution surface may be regarded as a melt gap.

Accordingly, the inert gas supplied from the upper side of the chamber 110 passes through the space between a lower inner circumferential surface of the heat shielding member 140 and the single crystal ingot (IG) and flows along a space between a lower end of the heat shielding member 140 and the silicon melt solution surface.

However, although the inert gas having a constant flow velocity is charged into the chamber 110, it is difficult to constantly control the flow velocity as a volume of the flow path through which the inert gas flows into the chamber 110 is changed. Accordingly, in order to constantly control a flow velocity of the inert gas flowing along a surface of the silicon melt solution, a gap between the heat shielding member 140 and the single crystal ingot (IG), and a gap between the heat shielding member 140 and the silicon melt solution surface should be adjusted.

In the embodiment, the flow velocity of the inert gas flowing along a surface of the silicon melt solution may be controlled depending on at least one of an inner diameter (d) of the heat shielding member 140, a length (L) of the tube 141, and a melt gap (M/G) varying with an elevating of the crucible 120.

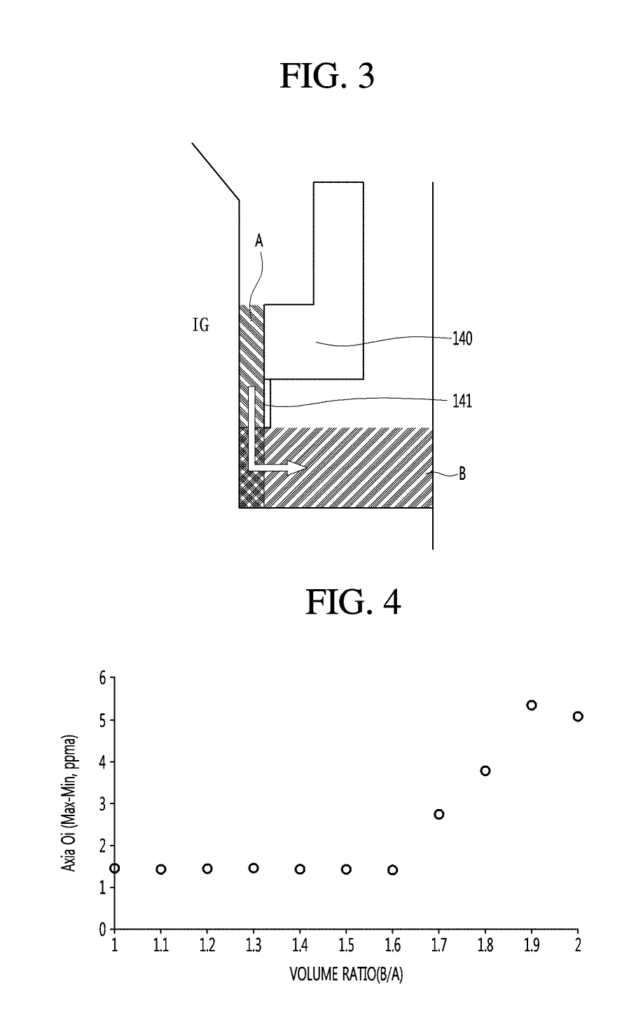

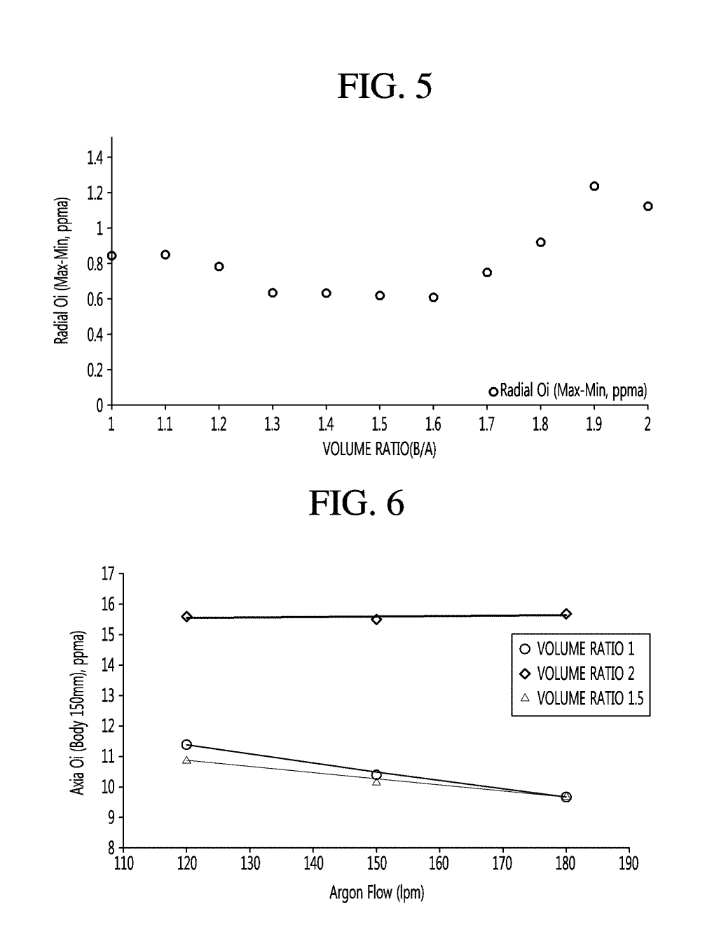

FIG. 3 is a schematic view schematically illustrating a main part of a flow path through which an inert gas flows according to the present invention, FIGS. 4 and 5 are graphs illustrating an oxygen concentration in an axial direction and a radial direction of the single crystal ingot according to a volume ratio change of the flow path shown in FIG. 3, and FIG. 6 is a graph illustrating an oxygen concentration and a flow velocity of an inert gas in an axial direction of the single crystal ingot depending on a volume ratio change of the flow path shown in FIG. 3.

According to the present invention, as shown in FIG. 3, a first flow path A in which the inert gas vertically moves downward is formed between an outer circumferential surface of the single crystal ingot (IG) and the inner circumferential surface of the heat shielding member 150, and a second flow path B in which the inert gas horizontally moves outward is formed between the lower end of the heat shielding member 140 and an upper surface of the silicon melt solution.

At this point, the flow velocity of the inert gas flowing along a surface of the silicon melt solution is maintained constantly depending on a volume ratio of the second flow path B to the first flow path A (hereinafter referred to as a volume ratio B/A of the first and second flow paths). Thus, an oxygen concentration in the single crystal can be uniformly controlled.

TABLE 1

| | Volume (based on ingot body 150 mm) | | | Flow velocity (based on ingot body 150 mm) | | | | | Single |
|---|---|---|---|---|---|---|---|---|---|
| | First flow | Second flow | Volume | First flow | Second flow | Flow velocity | Axial Oi | Radial Oi | crystal |
| Division | path A m³ | path B m³ | ratio (B/A) | path A cm/sec | path B cm/sec | ratio (B/A) | Deviation | Deviation | loss |
| 1 | 0.01 | 0.01 | 1 | 6.02 | 7.971 | 1.324 | 1.47 | 0.839 | ∘ |
| 2 | 0.01 | 0.011 | 1.1 | 6.02 | 7.577 | 1.259 | 1.44 | 0.839 | ∘ |
| 3 | 0.01 | 0.012 | 1.2 | 6.02 | 7.176 | 1.192 | 1.45 | 0.778 | ∘ |
| 4 | 0.01 | 0.013 | 1.3 | 6.02 | 6.77534 | 1.125 | 1.46 | 0.635 | ∘ |
| 5 | 0.01 | 0.014 | 1.4 | 6.02 | 6.38066 | 1.060 | 1.44 | 0.63 | x |
| 6 | 0.01 | 0.015 | 1.5 | 6.02 | 5.98 | 0.993 | 1.43 | 0.615 | x |
| 7 | 0.01 | 0.016 | 1.6 | 6.02 | 5.579 | 0.927 | 1.41 | 0.606 | x |
| 8 | 0.01 | 0.017 | 1.7 | 6.02 | 5.185 | 0.861 | 2.73 | 0.746 | x |
| 9 | 0.01 | 0.018 | 1.8 | 6.02 | 4.784 | 0.795 | 3.8 | 0.912 | x |
| 10 | 0.01 | 0.019 | 1.9 | 6.02 | 4.383 | 0.728 | 5.38 | 1.226 | x |
| 11 | 0.01 | 0.02 | 2 | 6.02 | 3.989 | 0.663 | 5.11 | 1.118 | x |

As shown in [Table 1] and FIG. 4, when the volume ratio (B/A) of the first and second flow paths is 1.7 or more, an oxygen concentration deviation becomes large in an axial direction of the single crystal ingot. In contrast, when the volume ratio (B/A) of the first and second flow paths is 1.6 or less, the oxygen concentration deviation in the axial direction of the single crystal becomes greatly reduced.

In addition, when the volume ratio (B/A) of the first and second flow paths is 1.3 or less, a single crystal loss increases even if the oxygen concentration deviation is small in the axial direction of the single crystal ingot, and thus it is difficult to stably advance the single crystal ingot growing process.

Accordingly, it is preferable that the volume ratio (B/A) of the first and second flow paths is limited to a range of 1.4 to 1.6 in order to reduce the oxygen concentration deviation in the axial direction of the single crystal. It is preferable that the volumes of the first and second flow paths A and B may be set such that a velocity deviation of the inert gas flowing along the first and second flow paths A and B is 0.5 cm/sec or less.

Further, as shown in FIG. 5, when the volume ratio (B/A) of the first and second flow paths is in the range of 1.4 to 1.6, it can be seen that the oxygen concentration deviation is also the lowest in a radial direction of the single crystal ingot.

As described above, when a target oxygen concentration is determined during the single crystal ingot growing process, the flow velocity of the inert gas may be uniformly controlled by appropriately changing the volume ratio (B/A) of the first and second flow paths. As a result, an oxygen concentration may be uniformly formed in the axial direction and the radial direction of the single crystal ingot.

TABLE 2

| | | | Target oxygen | | | |
|---|---|---|---|---|---|---|
| Volume | Ar flow | | concentration | Flow velocity (based on ingot body 150 mm) | | |
| Ratio | rate | Pressure | (based on ingot | First flow | Second flow | Flow velocity |
| (B/A) | lpm | torr | body 150 mm) | path A cm/sec | path B cm/sec | ratio (B/A) |
| 1 | 120 | 45 | 11.4 | 4.816 | 6.377 | 1.324 |
| | 150 | 45 | 10.4 | 6.02 | 7.971 | 1.324 |
| | 180 | 45 | 9.7 | 7.224 | 9.566 | 1.324 |
| 1.5 | 120 | 45 | 10.9 | 4.816 | 4.784 | 0.993 |
| | 150 | 45 | 10.2 | 6.02 | 5.98 | 0.993 |
| | 180 | 45 | 9.7 | 7.224 | 7.176 | 0.993 |
| 2 | 120 | 45 | 16.6 | 4.816 | 3.190928 | 0.663 |
| | 150 | 45 | 15.5 | 6.02 | 3.989 | 0.663 |
| | 180 | 45 | 15.7 | 7.224 | 4.786392 | 0.663 |

Meanwhile, when the target oxygen concentration is changed during the growth process of the single crystal ingot, since it is difficult to change the volumes of the first and second flow paths A and B, as shown in [Table 2] and FIG. 6, the flow velocity of the inert gas may be uniformly controlled by changing a flow rate of the inert gas charged into the chamber. As a result, the oxygen concentration in the single crystal can be uniformly formed.

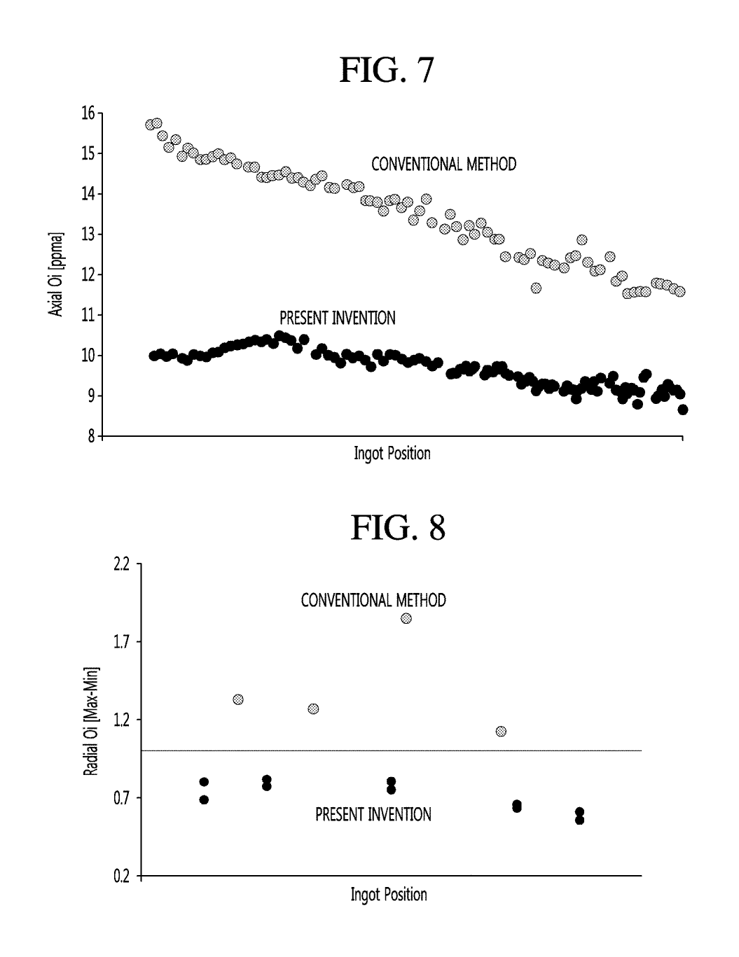

FIGS. 7 and 8 are graphs illustrating oxygen concentrations in an axial direction and a radial direction of the ingots manufactured by the conventional single crystal ingot growing apparatus and the single crystal ingot growing apparatus of the present invention.

According to the related art, since an oxygen concentration in the single crystal is controlled depending on an interval between the heat shielding member and the single crystal ingot, the oxygen concentration in the single crystal gradually decreases as the single crystal ingot grows more in an axial direction, and thus it can be seen that the oxygen concentration deviation (Max−Min) appears to be large in the axial direction and the radial direction of the single crystal ingot.

On the other hand, according to the present invention, since an oxygen concentration in the single crystal is controlled depending on an interval between the heat shielding member and the single crystal ingot, and a gap between the heat shielding member and the upper surface of the silicon melt solution, even if the single crystal ingot grows in an axial direction, it can be seen that the oxygen concentration in the single crystal maintains constantly, and the oxygen concentration deviation (Max-Min) is controlled to be 1.5 ppma or less in the axial direction of the single crystal ingot, and simultaneously the oxygen concentration deviation (Max−Min) is controlled to be 0.65 ppma or less in the radial direction of the single crystal ingot.

1. A single crystal ingot growing apparatus, comprising:
a crucible containing a silicon melt solution;
a heat shielding member mounted to hang above the crucible and cooling a single crystal ingot grown from the silicon melt solution of the crucible;
a first flow path formed between an outer circumferential surface of the single crystal ingot and an inner circumferential surface of the heat shielding member, in which an inert gas is vertically moved downward; and
a second flow path formed between a lower end of the heat shielding member and an upper surface of the silicon melt solution, in which the inert gas is horizontally moved outward,
wherein an oxygen concentration in the single crystal is controlled depending on a volume ratio of the second flow path to the first flow path.

2. The single crystal ingot growing apparatus of claim 1, wherein the volume ratio of the second flow path to the first flow path is limited to 1.4 to 1.6.

3. The single crystal ingot growing apparatus of claim 2, wherein the volumes of the first and second flow paths are set so that a velocity deviation of the inert gas flowing along the first and second flow paths is within 0.5 cm/sec.

4. The single crystal ingot growing apparatus of claim 2, wherein the oxygen concentration in the single crystal is controlled by changing a flow rate of the inert gas when a target oxygen concentration is changed during a growth process of the single crystal ingot.

5. The single crystal ingot growing apparatus of claim 1, further comprising: a tube extending downward at a lower side of the inner circumferential surface of the heat shielding member,
wherein the volume ratio of the second flow path to the first flow path is varied depending on at least one of an inner diameter (d) of the heat shielding member, a length (L) of the tube, and a melt gap (M/G).

6. The single crystal ingot growing apparatus of claim 5, wherein the volume ratio of the second flow path to the first flow path is set so as to control an oxygen concentration deviation (Max-Min) in an axial direction of the single crystal ingot to 1.5 ppma or less.

7. The single crystal ingot growing apparatus of claim 5, wherein the volume ratio of the second flow path to the first flow path is set so as to control an oxygen concentration deviation (Max−Min) in a radial direction of the single crystal ingot to 0.65 ppma or less.
